(19) United States
(12) Patent Application Publication
(10) Pub. No.: US 2019/0130856 A1
(43) Pub. Date: May 2, 2019

(54) SHIFT REGISTER UNITS, GATE DRIVING CIRCUITS, DISPLAY APPARATUSES AND DRIVING METHODS

(71) Applicants: BOE TECHNOLOGY GROUP CO., LTD., Beijing (CN); HEFEI BOE OPTOELECTRONICS TECHNOLOGY CO., LTD., Hefei (CN)

(72) Inventors: Yimin Chen, Beijing (CN); Xianjie Shao, Beijing (CN); Li Sun, Beijing (CN)

(21) Appl. No.: 15/953,391

(22) Filed: Apr. 13, 2018

(30) Foreign Application Priority Data
Oct. 31, 2017 (CN) 201711045547.3

(51) Int. Cl. G09G 3/36; G11C 19/28

(52) U.S. Cl. CPC G09G 3/3648; G09G 2320/0204; G09G 2310/0286; G11C 19/28

(57) ABSTRACT

A shift register unit, a gate driving circuit, a display apparatus and a driving method are provided. The shift register unit comprises a data register circuit and a data output circuit both electrically connected to a first node. The data register circuit is configured to register an input signal from an input terminal at the first node; and the data output circuit is configured to output the input signal registered at the first node to an output terminal in response to a first clock signal from a first clock signal terminal. The shift register unit can realize a self-resetting function. The first node can be reset under control of the first clock signal and a second clock signal from a second clock signal terminal.

### CROSS-REFERENCE TO RELATED APPLICATION(S)

This application claims priority to the Chinese Patent Application No. 201711045547.3, filed on Oct. 31, 2017, which is incorporated herein by reference in its entirety.

### TECHNICAL FIELD

The embodiments of the present disclosure relate to a shift register unit, a gate driving circuit, a display apparatus and a driving method.

### BACKGROUND

In the field of display technology, a pixel array of, for example, a liquid crystal display, typically comprises multiple rows of gate lines and multiple columns of data lines intersecting therewith. The gate lines may be driven by an integrated driving circuit which is attached thereto. In recent years, with the continuous improvement of the amorphous silicon film process, the driving circuit for the gate lines may also be directly integrated on a thin film transistor array substrate to form a Gate driver On Array (GOA), so as to drive the gate lines.

For example, the multiple rows of gate lines of the pixel array may be provided with a switch-state voltage signal by a GOA which is composed of a plurality of cascaded shift register units, so as to control the multiple rows of gate lines to be turned on sequentially and the corresponding rows of pixel units in the pixel array may be provided with a data signal by the data lines to form a grayscale voltage required for each grayscale of a display image and then display each frame image.

### SUMMARY

At least one embodiment of the present disclosure provides a shift register unit, comprising a data register circuit and a data output circuit both electrically connected to a first node. The data register circuit is configured to register an input signal from an input terminal at the first node; and the data output circuit is configured to output the input signal registered at the first node to an output terminal in response to a first clock signal from a first clock signal terminal. The first node can be reset under control of the first clock signal and a second clock signal from a second clock signal terminal.

In an example, in the shift register unit according to at least one embodiment of the present disclosure, the data storage circuit is electrically connected to a first voltage terminal, a second voltage terminal, the first clock signal terminal, the second clock signal terminal, the first node, and a second node. The data output circuit is electrically connected to the first voltage terminal, the second voltage terminal, the first clock signal terminal, and the first node.

In an example, in the shift register unit according to an embodiment of the present disclosure, the data register circuit comprises a first register circuit and a second register circuit electrically connected to a third node. The first register circuit is electrically connected to the first voltage terminal, the second voltage terminal, the first clock signal terminal, the second clock signal terminal, the second node, and the third node and is configured to invert and output the input signal to the third node so as to register inverted input signal at the third node. The second register circuit is electrically connected to the first voltage terminal, the second voltage terminal, the first node, and the third node, and is configured to invert and output a potential at the third node to the first node so as to register inverted potential at the first node.

In an example, in the shift register unit according to an embodiment of the present disclosure, the data output circuit comprises a logic NAND circuit and a first inverter circuit electrically connected to a fourth node. The logic NAND circuit is electrically connected to the first voltage terminal, the second voltage terminal, the first clock signal terminal, the first node, and the fourth node, and is configured to invert and output the input signal registered at the first node to the first inverter circuit when a high level is input from the first clock signal terminal. The first inverter circuit is electrically connected to the first voltage terminal, the second voltage terminal, and the fourth node, and is configured to invert and output the signal output by the logic NAND circuit to the output terminal.

In an example, the shift register unit according to an embodiment of the present disclosure further comprises a data input circuit. The data input circuit is electrically connected to the input terminal, the first voltage terminal, the second voltage terminal, and the second node, and is configured to input the input signal to the data register circuit.

In an example, in the shift register unit according to an embodiment of the present disclosure, the data input circuit comprises: a first transistor having a gate configured to be electrically connected to the first voltage terminal to receive a first voltage, a first electrode configured to be electrically connected to the input terminal to receive the input signal, and a second electrode configured to be electrically connected to the second node; and a second transistor having a gate configured to be electrically connected to the second voltage terminal to receive a second voltage, a first electrode configured to be electrically connected to the input terminal to receive the input signal, and a second electrode configured to be electrically connected to the second node. The first transistor is an N-type transistor and the second transistor is a P-type transistor.

In an example, in the shift register unit according to an embodiment of the present disclosure, the first register circuit comprises: a third transistor having a gate configured to be electrically connected to the first clock signal terminal to receive the first clock signal, and a first electrode configured to be electrically connected to the first voltage terminal to receive a first voltage; a fourth transistor having a gate configured to be electrically connected to the second node, a first electrode configured to be electrically connected to a second electrode of the third transistor, and a second electrode configured to be electrically connected to the third node; a fifth transistor having a gate configured to be electrically connected to the second node and a first electrode configured to be electrically connected to the second electrode of the fourth transistor; a sixth transistor having a gate configured to be electrically connected to the second clock signal terminal to receive the second clock signal, a first electrode configured to be electrically connected to a second electrode of the fifth transistor, and a second electrode configured to be electrically connected to the second voltage terminal to receive a second voltage; and a first storage capacitor having a first terminal configured to be electrically connected to the third node and a second terminal configured to be electrically connected to the second voltage terminal to receive the second voltage. The third transistor and the fourth transistor are P-type transistors and the fifth transistor and the sixth transistor are N-type transistors.

In an example, in the shift register unit according to an embodiment of the present disclosure, the second register circuit comprises: a seventh transistor having a gate configured to be electrically connected to the third node, a first electrode configured to be electrically connected to the first voltage terminal to receive a first voltage, and a second electrode configured to be electrically connected to the first node; an eighth transistor having a gate configured to be electrically connected to the third node, a first electrode configured to be electrically connected to the first node, and a second electrode configured to be electrically connected to the second voltage terminal to receive a second voltage; and a second storage capacitor having a first terminal configured to be electrically connected to the first node and a second terminal configured to be electrically connected to the second voltage terminal to receive the second voltage. The seventh transistor is a P-type transistor and the eighth transistor is an N-type transistor.

In an example, in the shift register unit according to an embodiment of the present disclosure, the logic NAND circuit comprises: a ninth transistor having a gate configured to be electrically connected to the first node, a first electrode configured to be electrically connected to the first voltage terminal to receive a first voltage, and a second electrode configured to be electrically connected to the fourth node; a tenth transistor having a gate configured to be electrically connected to the first clock signal terminal to receive the first clock signal, a first electrode configured to be electrically connected to the first voltage terminal to receive the first voltage, and a second electrode configured to be electrically connected to the fourth node; an eleventh transistor having a gate configured to be electrically connected to the first node and a first electrode configured to be electrically connected to the fourth node; and a twelfth transistor having a gate configured to be electrically connected to the first clock signal terminal to receive the first clock signal, a first electrode configured to be electrically connected to a second electrode of the eleventh transistor, and a second electrode configured to be electrically connected to the second voltage terminal to receive a second voltage. The ninth transistor and the tenth transistor are P-type transistors, and the eleventh transistor and the twelfth transistor are N-type transistors.

In an example, in the shift register unit according to an embodiment of the present disclosure, the first inverter circuit comprises: a thirteenth transistor having a gate configured to be electrically connected to the fourth node, a first electrode configured to be electrically connected to the first voltage terminal to receive a first voltage, and a second electrode configured to be electrically connected to the output terminal; and a fourteenth transistor having a gate configured to be electrically connected to the fourth node, a first electrode configured to be electrically connected to the output terminal, and a second electrode configured to be electrically connected to the second voltage terminal to receive a second voltage. The thirteenth transistor is a P-type transistor, and the fourteenth transistor is an N-type transistor.

In an example, the shift register unit according to an embodiment of the present disclosure further comprises a buffer de-noising circuit. The buffer de-noising circuit is electrically connected to the first voltage terminal, the second voltage terminal, the output terminal, and the data output circuit, and is configured to buffer, de-noise and output the signal output by the data output circuit to the output terminal.

In an example, in the shift register unit according to an embodiment of the present disclosure, the buffer de-noising circuit comprises a second inverter circuit and a third inverter circuit. The second inverter circuit is electrically connected to the first voltage terminal, the second voltage terminal, and the data output circuit, and is configured to invert and output the signal output by the data output circuit to the third inverter circuit. The third inverter circuit is electrically connected to the first voltage terminal, the second voltage terminal, and the output terminal, and is configured to invert and output the signal output by the second inverter circuit to the output terminal.

In an example, in the shift register unit according to an embodiment of the present disclosure, the second inverter circuit comprises: a fifteenth transistor having a gate configured to be electrically connected to the data output circuit, a first electrode configured to be electrically connected to the first voltage terminal to receive a first voltage, and a second electrode configured to be electrically connected to the third inverter circuit; and a sixteenth transistor having a gate configured to be electrically connected to the gate of the fifteenth transistor, a first electrode configured to be electrically connected to the second electrode of the fifteenth transistor, and a second electrode configured to be electrically connected to the second voltage terminal to receive a second voltage. The third inverter circuit comprises: a seventeenth transistor having a gate configured to be electrically connected to the second inverter circuit, a first electrode configured to be electrically connected to the first voltage terminal to receive the first voltage, and a second electrode configured to be electrically connected to the output terminal; and an eighteenth transistor having a gate configured to be electrically connected to the gate of the seventeenth transistor, a first electrode configured to be electrically connected to the second electrode of the seventeenth transistor, and a second electrode configured to be electrically connected to the second voltage terminal to receive the second voltage. The fifteenth transistor and the seventeenth transistor are P-type transistors, and the sixteenth transistor and the eighteenth transistor are N-type transistors.

At least one embodiment of the present disclosure further provides a gate driving circuit, comprising a plurality of cascaded shift register units according to any of the embodiments of the present disclosure.

At least one embodiment of the present disclosure further provides a display apparatus, comprising the driving apparatus according to any of the embodiments of the present disclosure.

At least one embodiment of the present disclosure further provides a driving method of the shift register unit, comprising: in a first phase, providing the first clock signal at a low level and the second clock signal at a high level, and registering, by the data register circuit, the input signal at the first node; in a second phase, providing the first clock signal at a high level and the second clock signal at a low level, and outputting, by the data output circuit, the input signal registered at the first node to the output terminal; and in a third phase, providing the first clock signal at a low level and the second clock signal at a high level, resetting, by the data register circuit, the first node and resetting, by the data output circuit, the output terminal.

### BRIEF DESCRIPTION OF THE DRAWINGS

In order to describe the technical solutions according to the embodiments of the present disclosure more clearly, the accompanying drawings of the embodiments are introduced briefly below. Obviously, the accompanying drawings in the following description relate to only some embodiments of the present disclosure rather than limiting the present disclosure.

FIG. 1 is a diagram of a shift register unit according to an example of an embodiment of the present disclosure;

FIG. 2 is a diagram of a shift register unit according to another example of an embodiment of the present disclosure;

FIG. 3 is a diagram of a shift register unit according to yet another example of an embodiment of the present disclosure;

FIG. 4 is a circuit diagram of a specific implementation example of the shift register unit shown in FIG. 2;

FIG. 5 is a circuit diagram of a specific implementation example of the shift register unit shown in FIG. 3;

FIG. 6 is a signal timing diagram when the shift register unit shown in FIG. 5 is in operation;

FIG. 7 is a diagram of a gate driving circuit according to an example of an embodiment of the present disclosure;

FIG. 8 is a signal timing diagram when the shift register unit shown in FIG. 7 is in operation;

FIG. 9 is a diagram of a gate driving circuit according to another example of an embodiment of the present disclosure; and

FIG. 10 is a diagram of a display apparatus according to an embodiment of the present disclosure.

### DETAILED DESCRIPTION

In order to make the purposes, technical solutions, and advantages of the embodiments of the present disclosure more clear, the technical solutions according to the embodiments of the present disclosure are clearly and completely described below with reference to the accompanying drawings of the embodiments of the present disclosure. Obviously, the described embodiments are only a part but not all of the embodiments of the present disclosure. All other embodiments obtained by those of ordinary skill in the art based on the described embodiments of the present disclosure without creative efforts shall fall within the protection scope of the present disclosure.

Unless otherwise defined, technical terms or scientific terms used in the present disclosure should be interpreted in the ordinary sense for those of ordinary skill in the art to which the present disclosure belongs. The words such as “first,” “second,” etc. used in the present disclosure do not mean any order, quantity or importance, but merely serve to distinguish different constituent parts. Similarly, “a”, “an” or “the” does not mean a limitation of quantity but means that at least one exists. The word such as “including” or “comprising” etc. means that an element or item preceding the word covers elements or items which appear after the word and their equivalents, but does not exclude other elements or items. The word “connected” or “connection” etc. is not limited to physical or mechanical connections but may comprise electrical connections, regardless of direct connections or indirect connections. “Up,” “down,” “left,” “right,” etc. are used only to represent a relative positional relationship, which may also change correspondingly when absolute positions of described objects change.

In the display panel technology, the Gate driver On Array (GOA) technology may be used to realize a low cost and a narrow bezel. That is, a gate driving circuit is integrated on a display panel through a thin film transistor process, so that advantages such as the narrow bezel and the low assembly cost can be realized. For example, the display panel may be a Liquid Crystal Display (LCD) panel or an Organic Light Emitting Diode (OLED) display panel.

At least one embodiment of the present disclosure provides a shift register unit, which comprises a data register circuit and a data output circuit. The data register circuit is configured to register an input signal at a first node, and the first node may be reset in response to a first clock signal and a second clock signal. The data output circuit is configured to output the input signal registered at the first node to an output terminal in response to the first clock signal. The embodiments of the present disclosure further provide a gate driving circuit, a display apparatus and a driving method corresponding to the shift register unit described above.

The shift register unit, the gate driving circuit, the display apparatus, and the driving method according to the embodiments of the present disclosure can realize a self-resetting function while reducing stress time of transistors, thereby prolonging the lifetime of the shift register unit and improving the stability of the shift register unit.

The embodiments of the present disclosure and examples thereof will be described in detail below with reference to the accompanying drawings.

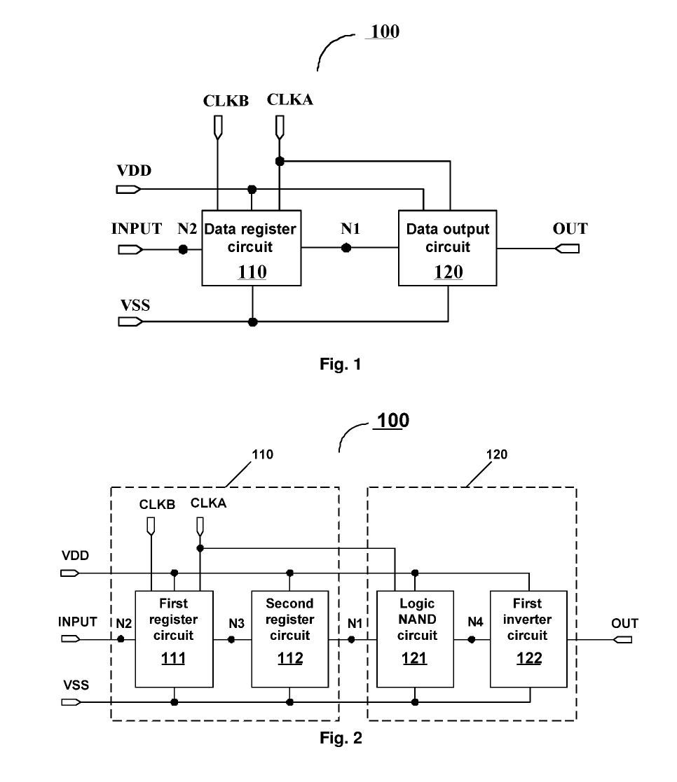

An example of an embodiment of the present disclosure provides a shift register unit 100. As shown in FIG. 1, the shift register unit 100 comprises a data register circuit 110 and a data output circuit 120.

The data register circuit 110 is configured to register an input signal at the first node N1.

For example, the data register circuit 110 may be configured to be electrically connected to a first voltage terminal VDD, a second voltage terminal VSS, a first clock signal terminal CLKA, a second clock signal terminal CLKB, the first node N1 and a second node N2, to electrically connect the first node N1 to the first voltage terminal VDD under control of a first clock signal input from the first clock signal terminal CLKA and a second clock signal input from the second clock signal terminal CLKB, so that the input signal may be registered at the first node N1.

It should be illustrated that the second node N2 may be configured to be electrically connected directly to an input terminal INPUT, or may also be configured to be electrically connected to the input terminal INPUT via other circuits, to receive the input signal, which is not limited in the embodiment of the present disclosure. The input signal is output to the second node N2 via the input terminal INPUT.

The first node N1 can be reset under control of the first clock signal from the first clock signal terminal CLKA and the second clock signal from the second clock signal terminal CLKB. For example, the data register circuit 110 may further be configured to electrically connect the first node N1 to the second voltage terminal VSS under control of the first clock signal input from the first clock signal terminal CLKA and the second clock signal input from the second clock signal terminal CLKB, so that a potential at the first node N1 may be pulled down to be reset.

For example, the first voltage terminal VDD may be configured to have a high level direct current signal input thereto, the second voltage terminal VSS may be configured to have a low level direct current signal input thereto, and the input signal is a high level valid signal. This is true in the following embodiments, and will not be repeated again.

For example, as shown in FIG. 2, in an example of the embodiment of the present disclosure, the data register circuit 110 may comprise a first register circuit 111 and a second register circuit 112.

For example, the first register circuit 111 may be electrically connected to the first voltage terminal VDD, the second voltage terminal VSS, the first clock signal terminal CLKA, the second clock signal terminal CLKB, the second node N2, and a third node N3, and may be configured to invert and output the input signal to the third node N3 so as to register the inverted input signal at the third node N3. For example, the first register circuit 111 may be configured to electrically connect the third node N3 to the first voltage terminal VDD or the second voltage terminal VSS under control of a potential at the second node N2, the first clock signal input from the first clock signal terminal CLKA, and the second clock signal input from the second clock signal terminal CLKB, so that the input signal may be inverted and output to the third node N3 so as to be registered at the third node N3.

For example, the second register circuit 112 may be electrically connected to the first voltage terminal VDD, the second voltage terminal VSS, the first node N1 and the third node N3, and may be configured to invert and output a potential at the third node N3 to the first node N1 so as to register the inverted potential at the first node N1. For example, the second register circuit 112 may be configured to electrically connect the first node N1 to the first voltage terminal VDD or the second voltage terminal VSS under control of the potential at the third node N3, so that the potential at the third node N3 may be inverted and output to the first node N1 so as to be registered at the first node N1.

The data output circuit 120 is configured to output the input signal registered at the first node N1 to the output terminal OUT in response to the first clock signal.

For example, the data output circuit 120 may be configured to be electrically connected to the first voltage terminal VDD, the second voltage terminal VSS, the first clock signal terminal CLKA and the first node N1, to electrically connect the output terminal OUT to the first voltage terminal VDD under control of the potential at the first node N1 and the first clock signal input from the first clock signal terminal CLKA, so that the input signal registered at the first node N1 may be output to the output terminal OUT.

It should be illustrated that the data output circuit 120 may be electrically connected directly to the output terminal OUT or may also be electrically connected to the output terminal OUT via other circuits to output a corresponding signal, which is not limited in the embodiment of the present disclosure.

For example, as shown in FIG. 2, in an example of the embodiment of the present disclosure, the data output circuit 120 may comprise a logic NAND circuit 121 and a first inverter circuit 122.

For example, the logic NAND circuit 121 may be electrically connected to the first voltage terminal VDD, the second voltage terminal VSS, the first clock signal terminal CLKA, the first node N1, and a fourth node N4, and may be configured to invert and output the input signal registered at the first node N1 to the first inverter circuit 122 when a high level signal is input from the first clock signal terminal CLKA. For example, the logic NAND circuit 121 may be configured to electrically connect the fourth node N4 to the first voltage terminal VDD or the second voltage terminal VSS under control of the potential at the first node N1 and the high level signal input from the first clock signal terminal CLKA, so that the input signal registered at the first node N1 may be inverted and output to the first inverter circuit 122.

For example, the first inverter circuit 122 may be electrically connected to the first voltage terminal VDD, the second voltage terminal VSS and the fourth node N4, and may be configured to invert and output the signal output by the logic NAND circuit 121 to the output terminal OUT. For example, the first inverter circuit 122 may be configured to electrically connect the output terminal OUT to the first voltage terminal VDD or the second voltage terminal VSS under control of a potential at the fourth node N4, so that the signal output by the logic NAND circuit 121 may be inverted and output to the output terminal OUT.

For example, a plurality of cascaded shift register units 100 described above may be used to form a gate driving circuit. When the display apparatus is driven by using the gate driving circuit, output of a gate scanning signal and self-resetting of the shift register unit 100 can be realized through cooperation of the first clock signal input from the first clock signal terminal CLKA and the second clock signal input from the second clock signal terminal CLKB.

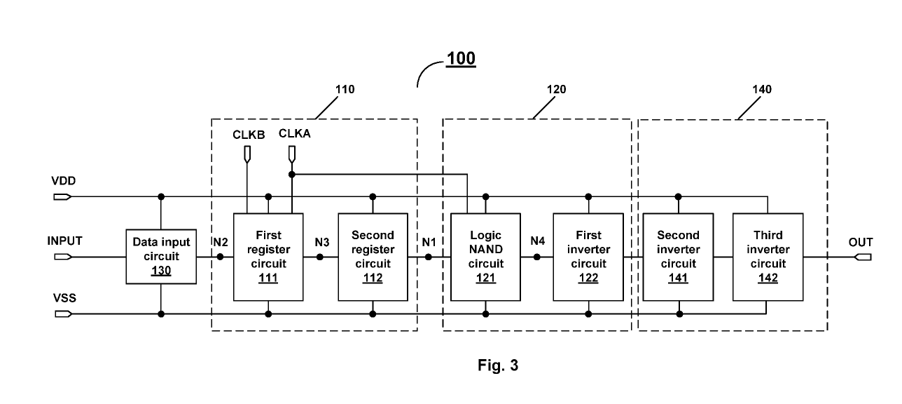

For example, as shown in FIG. 3, in an example of the embodiment of the present disclosure, the shift register unit 100 may further comprise a data input circuit 130.

For example, the data input circuit 130 may be electrically connected to the input terminal INPUT, the first voltage terminal VDD, the second voltage terminal VSS, and the second node N2, and may be configured to input the input signal to the data register circuit 110. For example, the input circuit 130 may be configured to electrically connect the input terminal INPUT to the second node N2 under control of a first voltage input from the first voltage terminal VDD and a second voltage input from the second voltage terminal VSS, so that the input signal may be input to the second node N2, that is, to the data register circuit 110.

It should be illustrated that, in the embodiment of the present disclosure, the first voltage terminal VDD has, for example, a high level direct current signal input thereto, which is referred to as the first voltage; and the second voltage terminal VSS has, for example, a low level direct current signal input thereto, which is referred to as the second voltage. This is true in the following embodiments and will not be repeated again.

For example, as shown in FIG. 3, in another example of the embodiment of the present disclosure, the shift register unit 100 may further comprise a buffer de-noising circuit 140 after the output circuit 120.

For example, the buffer de-noising circuit 140 may be electrically connected to the first voltage terminal VDD, the second voltage terminal VSS, the output terminal OUT and the data output circuit 120, and may be configured to buffer, de-noise and output the signal output by the data output circuit 120 to the output terminal OUT.

For example, in an example, as shown in FIG. 3, the buffer de-noising circuit 140 may comprise a second inverter circuit 141 and a third inverter circuit 142.

For example, the second inverter circuit 141 may be electrically connected to the first voltage terminal VDD, the second voltage terminal VSS, and the data output circuit 120, and may be configured to invert and output the signal output by the data output circuit 120 to the third inverter circuit 142.

For example, the third inverter circuit 142 may be electrically connected to the first voltage terminal VDD, the second voltage terminal VSS, and the output terminal OUT, and may be configured to invert and output the signal output by the second inverter circuit 141 to the output terminal OUT.

Thus, the signal output by the data output circuit 120 can be inverted twice by the second inverter circuit 141 and the third inverter circuit 142 in the buffer de-noising circuit 140 to achieve buffering and de-noising of the signal.

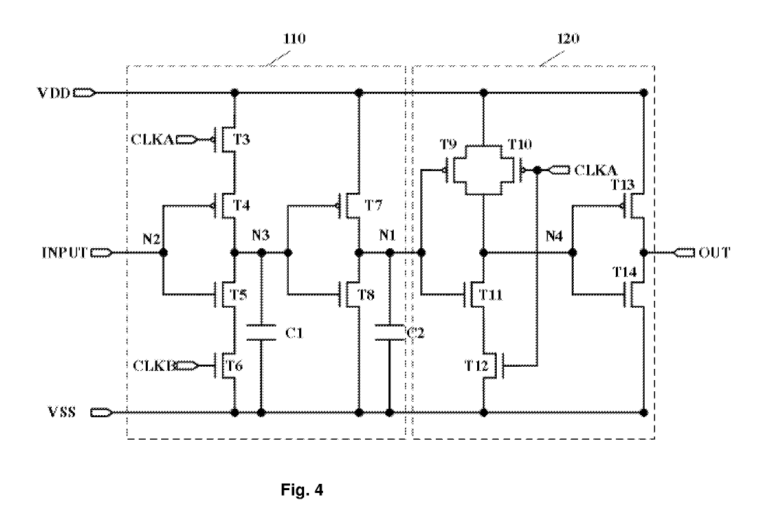

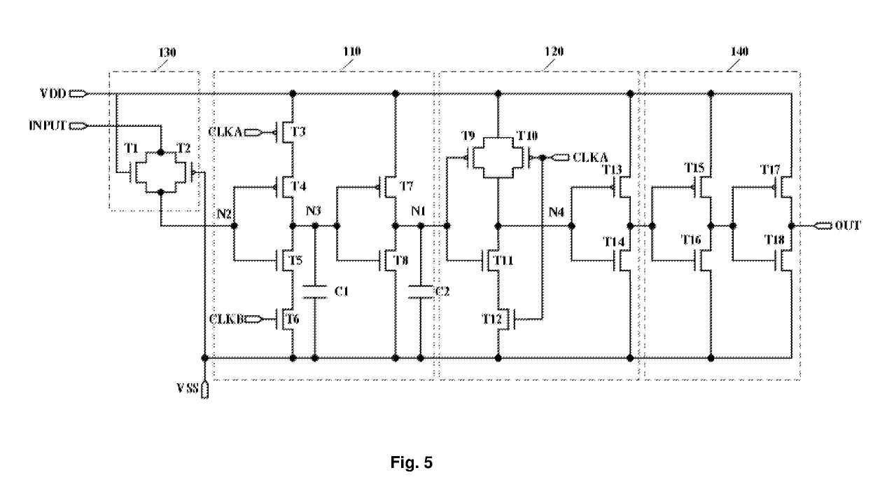

For example, the shift register unit 100 shown in FIG. 2 may be specifically implemented as a circuit structure shown in FIG. 4 in an example. As shown in FIG. 4, the shift register unit 100 comprises third to fourteenth transistors T3-T14, a first storage capacitor C1, and a second storage capacitor C2.

As shown in FIG. 4, more specifically, the first register circuit 111 may be implemented as the third to sixth transistors T3-T6 and the first storage capacitor C1. For example, the third transistor T3 has a gate configured to be electrically connected to the first clock signal terminal CLKA to receive the first clock signal, and a first electrode configured to be electrically connected to the first voltage terminal VDD to receive the first voltage; the fourth transistor T4 has a gate configured to be electrically connected to the second node N2, a first electrode configured to be electrically connected to a second electrode of the third transistor T3, and a second electrode configured to be electrically connected to the third node N3; the fifth transistor T5 has a gate configured to be electrically connected to the second node N2, and a first electrode configured to be electrically connected to the second electrode of the fourth transistor T4; the sixth transistor T6 has a gate configured to be electrically connected to the second clock signal terminal CLKA to receive the second clock signal, a first electrode configured to be electrically connected to a second electrode of the fifth transistor T5, and a second electrode configured to be electrically connected to the second voltage terminal VSS to receive the second voltage; and the first storage capacitor C1 has a first terminal configured to be electrically connected to the third node N3 and a second electrode configured to be electrically connected to the second voltage terminal VSS to receive the second voltage. For example, the third transistor T3 and the fourth transistor T4 are P-type transistors, and the fifth transistor T5 and the sixth transistor T6 are N-type transistors.

The second register circuit 112 may be implemented as the seventh transistor T7, the eighth transistor T8, and the second storage capacitor C2. For example, the seventh transistor T7 has a gate configured to be electrically connected to the third node N3, a first electrode configured to be electrically connected to the first voltage terminal VDD to receive the first voltage, and a second electrode configured to be electrically connected to the first node N1; the eighth transistor T8 has a gate configured to be electrically connected to the third node N3, a first electrode configured to be electrically connected to the first node N1, and a second electrode configured to be electrically connected to the second voltage terminal VSS to receive the second voltage; and the second storage capacitor C2 has a first terminal configured to be electrically connected to the first node N1 and a second terminal configured to be electrically connected to the second voltage terminal VSS to receive the second voltage. For example, the seventh transistor T7 is a P-type transistor and the eighth transistor T8 is an N-type transistor.

The logic NAND circuit 121 may be implemented as the ninth to twelfth transistors T9-T12. For example, the ninth transistor T9 has a gate configured to be electrically connected to the first node N1, a first electrode configured to be electrically connected to the first voltage terminal VDD to receive the first voltage, and a second electrode configured to be electrically connected to the fourth node N4; the tenth transistor T10 has a gate configured to be electrically connected to the first clock signal terminal CLKA to receive the first clock signal, a first electrode configured to be electrically connected to the first voltage terminal VDD to receive the first voltage, and a second electrode configured to be electrically connected to the fourth node N4; the eleventh transistor T11 has a gate configured to be electrically connected to the first node N1, and a first electrode configured to be electrically connected to the fourth node N4; the twelfth transistor T12 has a gate configured to be electrically connected to the first clock signal terminal CLKA to receive the first clock signal, a first electrode configured to be electrically connected to a second electrode of the eleventh transistor T11, and a second electrode configured to be electrically connected to the second voltage terminal VSS to receive the second voltage. For example, the ninth transistor T9 and the tenth transistor T10 are P-type transistors, and the eleventh transistor T11 and the twelfth transistor T12 are N-type transistors.

The first inverter circuit 122 may be implemented as the thirteenth transistor T13 and the fourteenth transistor T14. For example, the thirteenth transistor T13 has a gate configured to be electrically connected to the fourth node N4, a first electrode configured to be electrically connected to the first voltage terminal VDD to receive the first voltage, and a second electrode configured to be electrically connected to the output terminal OUT; and the fourteenth transistor T14 has a gate configured to be electrically connected to the fourth node N4, a first electrode configured to be electrically connected to the output terminal OUT, and a second electrode configured to be electrically connected to the second voltage terminal VSS to receive the second voltage. For example, the thirteenth transistor T13 is a P-type transistor and the fourteenth transistor T14 is an N-type transistor.

The shift register unit 100 shown in FIG. 3 may be specifically implemented as the circuit structure shown in FIG. 5 in an example. As shown in FIG. 5, the shift register unit 100 is different from the shift register unit 100 shown in FIG. 4 in that the shift register unit 100 further comprises a first transistor T1, a second transistor T2, and fifteenth to eighteenth transistors T15-T18.

As shown in FIG. 5, more specifically, the data input circuit 130 may be implemented as the first transistor T1 and the second transistor T2. For example, the first transistor T1 has a gate configured to be electrically connected to the first voltage terminal VDD to receive the first voltage, a first electrode configured to be electrically connected to the input terminal INPUT to receive the input signal, and a second electrode configured to electrically connected to the second node N2; and the second transistor T2 has a gate configured to be electrically connected to the second voltage terminal VSS to receive the second voltage, a first electrode configured to be electrically connected to the input terminal INPUT to receive the input signal, and a second electrode configured to be electrically connected to the second node N2. For example, the first transistor T1 is an N-type transistor and the second transistor T2 is a P-type transistor.

It should be illustrated that in some embodiments of the present disclosure, the data input circuit 130 may also comprise only the first transistor T1 or only the second transistor T2, which is not limited in the embodiment of the present disclosure.

The second inverter circuit 141 may be implemented as the fifteenth transistor T15 and the sixteenth transistor T16. For example, the fifteenth transistor T15 has a gate configured to be electrically connected to the data output circuit 120, a first electrode configured to be electrically connected to the first voltage terminal VDD to receive the first voltage, and a second electrode configured to be electrically connected to the third inverter circuit 142; and the sixteenth transistor T16 has a gate configured to be electrically connected to the gate of the fifteenth transistor T15, a first electrode configured to be electrically connected to the second electrode of the fifteenth transistor T15, and a second electrode configured to be electrically connected to the second voltage terminal VSS to receive the second voltage. For example, the fifteenth transistor T15 is a P-type transistor and the sixteenth transistor T16 is an N-type transistor.

The third inverter circuit 142 may be implemented as the seventeenth transistor T17 and the eighteenth transistor T18. For example, the seventeenth transistor T17 has a gate configured to be electrically connected to the second inverter circuit 141, a first electrode configured to be electrically connected to the first voltage terminal VDD to receive the first voltage, and a second electrode configured to be electrically connected to the output terminal OUT; and the eighteenth transistor T18 has a gate configured to be electrically connected to the gate of the seventeenth transistor T17, a first electrode electrically connected to the second electrode of the seventeenth transistor T17, and a second electrode electrically connected to the second voltage terminal VSS to receive the second voltage. For example, the seventeenth transistor T17 is a P-type transistor and the eighteenth transistor T18 is an N-type transistor.

A relationship of electrical connections of other transistors and the first storage capacitor C1 and the second storage capacitor C2 in FIG. 5 can be known with reference to a corresponding description of the shift register unit 100 shown in FIG. 4, which will not be repeated here.

It should be illustrated that all the transistors used in the embodiments of the present disclosure may be thin film transistors, field effect transistors, or other switch devices having the same characteristics. In the embodiments of the present disclosure, thin film transistors are taken as an example for description. A source and a drain of each transistor used here may be structurally symmetrical, and therefore there is no difference between the source and drain thereof in structure. In the embodiments of the present disclosure, in order to distinguish two electrodes except for a gate of the transistor, one of the electrodes is directly described as a first electrode, and the other of the electrodes is directly described as a second electrode.

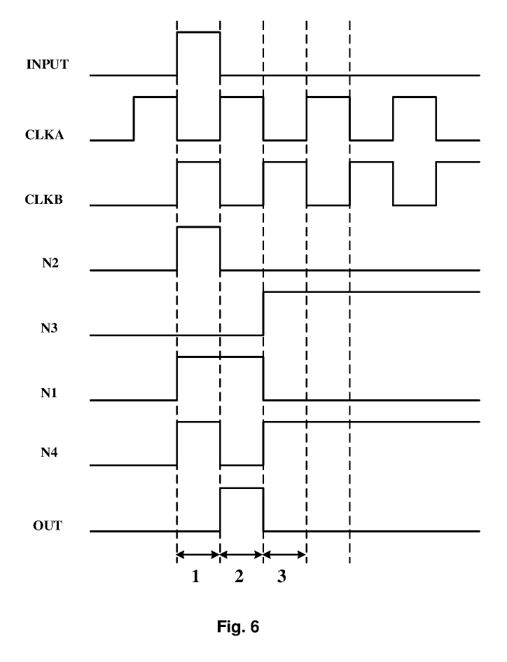

FIG. 6 is a signal timing diagram when the shift register unit 100 shown in FIG. 5 is in operation. The operation principle of the shift register unit shown in FIG. 5 will be described below with reference to the signal timing diagram shown in FIG. 6. In a first phase 1, a second phase 2 and a third phase 3 shown in FIG. 6, the shift register unit 100 may operate as follows.

In the first phase 1, a high level is input from the input terminal INPUT, a low level is input from the first clock signal terminal CLKA, a high level is input from the second clock signal terminal CLKB, a high level is input from the first voltage terminal VDD, and a low level is input from the second voltage terminal VSS. As the high level is input from the first voltage terminal VDD, the first transistor T1 is turned on, and as the low level is input from the second voltage terminal VSS, the second transistor T2 is turned on, to electrically connect the input terminal INPUT to the second node N2, so that the high level input from the input terminal INPUT is output to the second node N2.

As the potential at the second node N2 is at a high level, the low level is input from the first clock signal terminal CLKA and the high level is input from the second clock signal terminal CLKB, the fourth transistor T4 is turned off, and the third transistor T3, the fifth transistor T5 and the sixth transistor T6 are turned on, to electrically connect the third node N3 to the second voltage terminal VSS, so that the first storage capacitor C1 may be discharged through the fifth transistor T5 and the sixth transistor T6, to pull down the potential at the third node N3 to a low level.

As the potential at the third node N3 is at a low level, the seventh transistor T7 is turned on, and the eighth transistor T8 is turned off, to electrically connect the first node N1 to the first voltage terminal VDD, so that the second storage capacitor C2 may be charged by the high level input from the first voltage terminal VDD to pull up the potential at the first node N1 to a high level. In this phase, the high level signal input from the input terminal INPUT is registered at the first node N1.

As the potential at the first node N1 is at a high level, and the low level is input from the first clock signal terminal CLKA, the ninth transistor T9 and the twelfth transistor T12 are turned off, and the tenth transistor T10 and the eleventh transistor T11 are turned on, to electrically connect the fourth node N4 to the first voltage terminal VDD, to pull up the potential at the fourth node N4 to a high level.

As the potential at the fourth node N4 is at a high level, the thirteenth transistor T13 is turned off and the fourteenth transistor T14 is turned on, so that a low level signal from the second voltage terminal VSS is output by the data output circuit 120.

As the second inverter circuit 141 is electrically connected to the data output circuit 120, in which case the low level signal output by the data output circuit 120 is output to the second inverter circuit 141, the fifteenth transistor T15 is turned on and the sixteenth transistor T16 is turned off, to electrically connect an output terminal of the second inverter circuit 141 to the first voltage terminal VDD, so that a high level signal is output by the second inverter circuit 141.

As the third inverter circuit 142 is electrically connected to the second inverter circuit 141, in which case the high level signal output by the second inverter circuit 141 is output to the third inverter circuit 142, the seventeenth transistor T17 is turned off, and the eighteenth transistor T18 is turned on, to electrically connect the output terminal OUT to the second voltage terminal VSS to pull down the potential at the output terminal OUT to a low level. Thereby, in this phase, a low level signal is output by the output terminal OUT.

In the first phase 1, the input signal input from the input terminal INPUT is registered in the data register circuit 110 under control of the first clock signal input from the first clock signal terminal CLKA and the second clock signal input from the second clock signal terminal CLKB.

In the second phase 2, a low level is input from the input terminal INPUT, a high level is input from the first clock signal terminal CLKA, a low level is input from the second clock signal terminal CLKB, the high level is still input from the first voltage terminal VDD, and the low level is still input from the second voltage terminal VSS. As the high level is input from the first voltage terminal VDD and the low level is input from the second voltage terminal VSS, the first transistor T1 and the second transistor T2 are still turned on, to electrically connect the second node N2 to the input terminal INPUT, so that the low level input from the input terminal INPUT is output to the second node N2. Thereby, in this phase, the potential at the second node N2 is at a low level.

As the potential at the second node N2 is at a low level, the high level is input from the first clock signal terminal CLKA and the low level is input from the second clock signal terminal CLKB, the third transistor T3, the fifth transistor T5 and the sixth transistor T6 are turned off and the fourth transistor T4 is turned on, so that the first storage capacitor C1 enables the potential at the third node N3 to continue to be maintained at a low level.

As the potential at the third node N3 is at a low level, the potential at the first node N1 may continue to be maintained a high level registered in a previous phase.

As the potential at the first node N1 continues to be maintained in a high level state and the high level is input from the first clock signal terminal CLKA, the ninth transistor T9 and the tenth transistor T10 are turned off, and the eleventh transistor T11 and the twelfth transistor T12 are turned on, to electrically connect the fourth node N4 to the second voltage terminal VSS, to pull down the potential at the fourth node N4 to a low level.

As the potential at the fourth node N4 is at a low level, the thirteenth transistor T13 is turned on and the fourteenth transistor T14 is turned off, so that the high level signal input from the first voltage terminal VDD is output by the data output circuit 120.

As the second inverter circuit 141 is electrically connected to the data output circuit 120, in which case the high level signal is output by the data output circuit 120 to the second inverter circuit 141, the fifteenth transistor T15 is turned off, and the sixteenth transistor T16 is turned on, to electrically connect the output terminal of the second inverter circuit 141 to the second voltage terminal VSS, to pull down the signal output by the second inverter circuit 141 to a low level.

As the third inverter circuit 142 is electrically connected to the second inverter circuit 141, in which case the low level signal output by the second inverter circuit 141 is output to the third inverter circuit 142, the seventeenth transistor T17 is turned on, and the eighteen transistor T18 is turned off, to electrically connect the output terminal OUT to the first voltage terminal VDD, so that the high level signal input from the first voltage terminal VDD is output to the output terminal OUT. Therefore, in the second phase 2, the input signal registered at the first node N1 in the first phase 1 is output by the data output circuit 120 to the output terminal OUT, after being de-noised by the buffer de-noising circuit 140.

In the second phase 2, the input signal registered in the data register circuit 110 in the first phase 1 is buffered, de-noised and output to the output terminal OUT under control of the first clock signal input from the first clock signal terminal CLKA and the second clock signal input from the second clock signal terminal CLKB.

In the third phase 3, a low level is input from the first clock signal terminal CLKA, a high level is input from the second clock signal terminal CLKB, a low level is input from the input terminal INPUT, the high level is still input from the first voltage terminal VDD, and the low level is still input from the second voltage terminal VSS. As the high level is input from the first voltage terminal VDD and the low level is input from the second voltage terminal VSS, the first transistor T1 and the second transistor T2 are still turned on, to electrically connect the second node N2 to the input terminal INPUT, so that the low level input from the input terminal INPUT is output to the second node N2. Thereby, in this phase, the potential at the second node N2 is at a low level.

As the potential at the second node N2 is at a low level, the low level is input from the first clock signal terminal CLKA and the high level is input from the second clock signal terminal CLKB, the third transistor T3, the fourth transistor T4 and the sixth transistor T6 are turned on, and the fifth transistor T5 is turned off, to electrically connect the third node N3 to the first voltage terminal VDD, so that the first storage capacitor C1 may be charged by the high level input from the first voltage terminal VDD, to pull up the potential at the third node N3 to a high level.

As the potential at the third node N3 is pulled up to a high level, the seventh transistor T7 is turned off and the eighth transistor T8 is turned on, to electrically connect the first node N1 to the second voltage terminal VSS, so that the second storage capacitor C2 may be discharged through the eighth transistor T8 to pull down the potential at the first node N1 to a low level, so as to reset the first node N1.

As the potential at the first node N1 is at a low level, and the low level is input from the first clock signal terminal CLKA, the ninth transistor T9 and the tenth transistor T10 are turned on, and the eleventh transistor T11 and the twelfth transistor T12 are turned off, to electrically connect the fourth node N4 to the first voltage terminal VDD, so that the potential at the fourth node N4 is pulled up to a high level.

As the potential at the fourth node N4 is at a high level, the thirteenth transistor T13 is turned off and the fourteenth transistor T14 is turned on, so that the low level signal from the second voltage terminal VSS is output by the data output circuit 120. The signal output by the data output circuit 120 is then buffered, de-noised and output by the buffer de-noising circuit 140 to the output terminal OUT. Thereby, in this phase, the output terminal OUT is pulled down to be reset.

In the third phase 3, the potential at the first node N1 is reset while realizing self-resetting of the output terminal OUT under control of the first clock signal input from the first clock signal terminal CLKA and the second clock signal input from the second clock signal terminal CLKB.

The shift register unit 100 according to the embodiments of the present disclosure can firstly register the input signal input from the input terminal INPUT in the data register circuit 110, and then buffer, de-noise and output the input signal registered in the data register circuit 110 to the output terminal OUT through the data output circuit 120 and the buffer de-noising circuit 130 when the high level signal is input from the first clock signal terminal CLKA, to realize output of a gate scanning signal. At the same time, the shift register unit can further realize self-resetting of the output terminal OUT through cooperation of the first clock signal input from the first clock signal terminal CLKA and the second clock signal input from the second clock signal terminal CLKB.

In addition, the shift register unit 100 according to the embodiments of the present disclosure can reduce the stress time of the transistors by combined use of the transistors and the storage capacitors, thereby prolonging the lifetime of the shift register unit 100 and increasing the stability of the shift register unit 100.

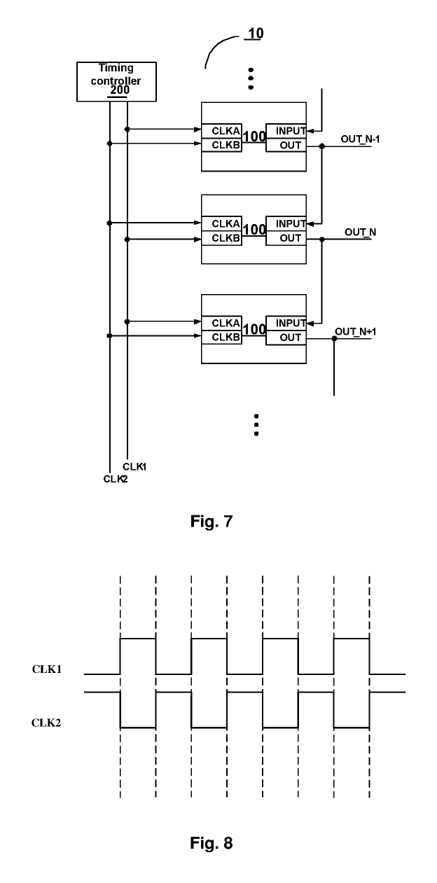

An example of an embodiment of the present disclosure provides a gate driving circuit 10. As shown in FIG. 7, the gate driving circuit 10 comprises a plurality of cascaded shift register units. For example, the shift register units may each be implemented by the shift register unit 100 according to the embodiments of the present disclosure. The gate driving circuit 10 may be integrated directly on an array substrate of a display apparatus using the same process as that for manufacturing a thin film transistor, to realize a progressive scanning and driving function.

It should be illustrated that only three shift register units 100 are schematically shown in FIG. 7, and the embodiments of the present disclosure comprise, but not limited to, the three shift register units 100.

For example, as shown in FIG. 7, an input terminal INPUT of each stage of shift register unit is electrically connected to an output terminal OUT of a previous stage of shift register unit except for a first stage of shift register unit. For example, an input terminal INPUT of the first stage of shift register unit may be configured to receive a trigger signal STV.

For example, as shown in FIG. 7, an output terminal of an (N−1)^{th} (where N is an integer greater than 1) stage of shift register unit is OUT_N−1, an output terminal of an N^{th} stage of shift register unit is OUT_N, and an output terminal of an (N+1)^{th} stage of shift register unit is OUT_N+1.

For example, when a display panel is driven by using the gate driving circuit 10, the gate driving circuit 10 may be provided on one side of the display panel. For example, the display panel comprises a plurality of rows of gate lines. Output terminals OUT of various stages of shift register units 100 in the gate driving circuit 10 may be configured to be sequentially electrically connected to the plurality of rows of gate lines to output a progressive scanning signal. It should be illustrated that the display panel may also have the gate driving circuit 10 provided on both sides thereof respectively to implement bilateral driving. An arrangement manner of the gate driving circuit 10 is not limited in the embodiments of the present disclosure.

For example, the gate driving circuit 10 may further comprise a first clock signal line CLK1 and a second clock signal line CLK2. For example, in this example, the first clock signal line CLK1 may be configured to be electrically connected to a first clock signal terminal CLKA of a (2n-1)^{th} (where n is an integer greater than 0) stage of shift register unit 100, and the second clock signal line CLK2 may be configured to be electrically connected to a second clock signal terminal CLKB of the (2n-1)^{th} stage of shift register unit 100; and the first clock signal line CLK1 may be configured to be electrically connected to a second clock signal terminal CLKB of a (2n)^{th} stage of shift register unit 100, and the second clock signal line CLK2 may be configured to be electrically connected to a first clock signal terminal CLKA of the (2n)^{th} stage of shift register unit 100.

For example, a timing shown in FIG. 8 may be used as a clock signal timing provided on the first clock signal line CLK1 and the second clock signal line CLK2.

As shown in FIG. 7, the gate driving circuit 10 may further comprise a timing controller 200. For example, the timing controller 200 may be configured to be electrically connected to the first clock signal line CLK1 and the second clock signal line CLK2 to provide a clock signal to each stage of shift register unit 100. The timing controller 200 may further be configured to provide the trigger signal STV.

The gate driving circuit 10 according to the embodiments of the present disclosure may output a gate progressive scanning signal and can realize self-resetting of an output terminal OUT of each stage of shift register unit 100 through cooperation of the first clock signal and the second clock signal.

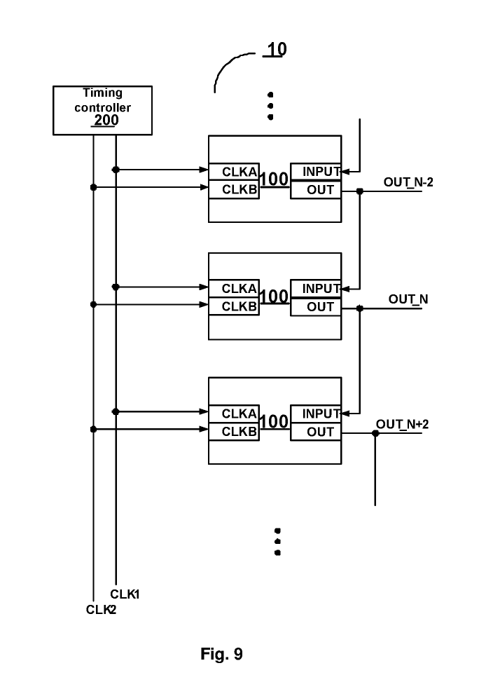

For example, as shown in FIG. 9, another example of the embodiment of the present disclosure provides a gate driving circuit 10 comprising a plurality of cascaded shift register units. For example, the shift register units may each be implemented by the shift register unit 100 according to the embodiments of the present disclosure. The gate driving circuit 10 can be integrated directly on an array substrate of a display apparatus using the same process as that for manufacturing a thin film transistor to realize a progressive scanning and driving function.

It should be illustrated that only three shift register units 100 are schematically shown in FIG. 9. The embodiments of the present disclosure comprises, but not limited to, the three shift register units 100.

For example, as shown in FIG. 9, an input terminal INPUT of each stage of shift register unit is electrically connected to an output terminal OUT of a previous stage of shift register unit except for a first stage of shift register unit. For example, an input terminal INPUT of the first stage of shift register unit may be configured to receive a trigger signal STV.

For example, as shown in FIG. 9, an output terminal of an (N−2)^{th} (where N is an integer greater than 2) stage of shift register unit is OUT_N−2, an output terminal of an N^{th} stage of shift register unit is OUT_N, and an output terminal of an (N+2)^{th} stage of shift register unit is OUT_N+2.

In this example, when a display panel is driven by using the gate driving circuit 10, the display panel may have the gate driving circuit 10 provided on one side thereof to drive odd rows of gate lines and have the gate driving circuit 10 provided on the other side thereof to drive even rows of gate lines.

For example, the gate driving circuit 10 may further comprise a first clock signal line CLK1 and a second clock signal line CLK2. For example, in this example, the first clock signal line CLK1 may be configured to be electrically connected to a first clock signal terminal CLKA of each stage of shift register unit 100 and the second clock signal line CLK2 may be configured to be electrically connected to a second clock signal terminal CLKB of each stage of shift register unit 100.

It should be illustrated that the embodiments of the present disclosure comprise, but not limited to, for example, a situation that the first clock signal line CLK1 may further be configured to be electrically connected to the second clock signal terminal CLKB of each stage of shift register unit 100 and the second clock signal line CLK2 may further be configured to be electrically connected to the first clock signal terminal CLKA of each stage of shift register unit 100.

For example, the timing shown in FIG. 8 may be used as a clock signal timing provided on the first clock signal line CLK1 and the second clock signal line CLK2.

As shown in FIG. 9, the gate driving circuit 10 may further comprise a timing controller 200. For example, the timing controller 200 may be configured to be electrically connected to the first clock signal line CLK1 and the second clock signal line CLK2 to provide a clock signal to each stage of shift register unit 100. The timing controller 200 may further be configured to provide the trigger signal STV.

The gate driving circuit 10 according to the embodiments of the present disclosure may output a gate progressive scanning signal and can realize self-resetting of an output terminal OUT of each stage of shift register unit 100 through cooperation of the first clock signal and the second clock signal.

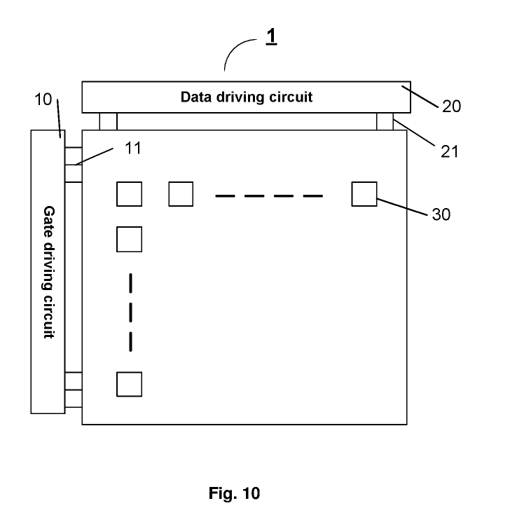

The embodiments of the present disclosure further provide a display apparatus 1. As shown in FIG. 10, the display apparatus 1 comprises the gate driving circuit 10 according to any of the embodiments of the present disclosure. The display apparatus 1 comprises an array composed of a plurality of pixel units 30. For example, the display apparatus 1 may further comprise a data driving circuit 20. The data driving circuit 20 is configured to provide a data signal to the pixel array. The gate driving circuit 10 is configured to provide a gate scanning signal to the pixel array. The data driving circuit 20 is electrically connected to the pixel units 30 through data lines 21. The gate driving circuit 10 is electrically connected to the pixel units 30 through gate lines 11.

It should be illustrated that the display apparatus 1 may be any product or component having a display function, such as a liquid crystal panel, a liquid crystal television, a display, an Organic Light Emitting Diode (OLED) panel, an OLED television, an electronic paper display apparatus, a mobile phone, a tablet computer, a notebook computer, a digital photo frame, a navigator etc. The display apparatus 1 may further comprise other conventional components such as a display panel, which is not limited in the embodiments of the present disclosure.

The technical effects of the display apparatus 1 according to the embodiments of the present disclosure can be known with reference to the corresponding description of the shift register unit 100 in the above embodiments, which will not be repeated here.

The embodiments of the present disclosure further provide a driving method which can be used to drive the shift register unit 100 according to any of the embodiments of the present disclosure. For example, the driving method comprises the following operations.

In a first stage, the first clock signal at a low level and the second clock signal at a high level are provided, and the input signal is registered by the data register circuit 110 at the first node N1.

In a second stage, the first clock signal at a high level and the second clock signal at a low level are provided, and the input signal registered at the first node N1 is output by the data output circuit 120 to the output terminal OUT.

In a third stage, the first clock signal at a low level and the second clock signal at a high level are provided, the first node N1 is reset by the data register circuit 110 and the output terminal OUT is reset by the data output circuit 120.

It should be illustrated that, a detailed description of the driving method can be known with reference to the description of the operation principle of the shift register unit 100 in the embodiments of the present disclosure, which will not be repeated here.

The driving method of the shift register unit according to the embodiments of the present disclosure can output a gate progressive scanning signal, and can realize self-resetting of the output terminal OUT through cooperation of the first clock signal and the second clock signal.

The foregoing description is merely specific implementations of the present disclosure, but the protection scope of the present disclosure is not limited thereto, and the protection scope of the present disclosure should be based on the protection scope of the claims.

I/We claim:

1. A shift register unit, comprising a data register circuit and a data output circuit, which are electrically connected to a first node, wherein:
the data register circuit is configured to register an input signal from an input terminal at the first node;
the data output circuit is configured to output the input signal registered at the first node to an output terminal in response to a first clock signal from a first clock signal terminal;
the first node can be reset under control of the first clock signal and a second clock signal from a second clock signal terminal.

2. The shift register unit according to claim 1, wherein:
the data storage circuit is electrically connected to a first voltage terminal, a second voltage terminal, the first clock signal terminal, the second clock signal terminal, the first node, and a second node; and
the data output circuit is electrically connected to the first voltage terminal, the second voltage terminal, the first clock signal terminal, and the first node.

3. The shift register unit according to claim 2, wherein the data register circuit comprises a first register circuit and a second register circuit, which are electrically connected to a third node, wherein:
the first register circuit is electrically connected to the first voltage terminal, the second voltage terminal, the first clock signal terminal, the second clock signal terminal, the second node, and the third node, and is configured to invert and output the input signal to the third node so as to register inverted input signal at the third node; and
the second register circuit is electrically connected to the first voltage terminal, the second voltage terminal, the first node, and the third node, and is configured to invert and output a potential at the third node to the first node so as to register inverted potential at the first node.

4. The shift register unit according to claim 2, wherein the data output circuit comprises a logic NAND circuit and a first inverter circuit, which are electrically connected to a fourth node, wherein:
the logic NAND circuit is electrically connected to the first voltage terminal, the second voltage terminal, the first clock signal terminal, the first node, and the fourth node, and is configured to invert and output the input signal registered at the first node to the first inverter circuit when a high level is input from the first clock signal terminal; and
the first inverter circuit is electrically connected to the first voltage terminal, the second voltage terminal, and the fourth node, and is configured to invert and output the signal output by the logic NAND circuit to the output terminal.

5. The shift register unit according to claim 2, further comprising a data input circuit, wherein:
the data input circuit is electrically connected to the input terminal, the first voltage terminal, the second voltage terminal, and the second node, and is configured to input the input signal to the data register circuit.

6. The shift register unit according to claim 5, wherein the data input circuit comprises:
a first transistor having a gate configured to be electrically connected to the first voltage terminal to receive a first voltage, a first electrode configured to be electrically connected to the input terminal to receive the input signal, and a second electrode configured to be electrically connected to the second node; and
a second transistor having a gate configured to be electrically connected to the second voltage terminal to receive a second voltage, a first electrode configured to be electrically connected to the input terminal to receive the input signal, and a second electrode configured to be electrically connected to the second node;
wherein the first transistor is an N-type transistor and the second transistor is a P-type transistor.

7. The shift register unit according to claim 3, wherein the first register circuit comprises:
a third transistor having a gate configured to be electrically connected to the first clock signal terminal to receive the first clock signal, and a first electrode configured to be electrically connected to the first voltage terminal to receive a first voltage;
a fourth transistor having a gate configured to be electrically connected to the second node, a first electrode configured to be electrically connected to a second electrode of the third transistor, and a second electrode configured to be electrically connected to the third node;
a fifth transistor having a gate configured to be electrically connected to the second node and a first electrode configured to be electrically connected to the second electrode of the fourth transistor;
a sixth transistor having a gate configured to be electrically connected to the second clock signal terminal to receive the second clock signal, a first electrode configured to be electrically connected to a second electrode of the fifth transistor, and a second electrode configured to be electrically connected to the second voltage terminal to receive a second voltage; and
a first storage capacitor having a first terminal configured to be electrically connected to the third node and a second terminal configured to be electrically connected to the second voltage terminal to receive the second voltage,
wherein the third transistor and the fourth transistor are P-type transistors and the fifth transistor and the sixth transistor are N-type transistors.

8. The shift register unit according to claim 3, wherein the second register circuit comprises:
a seventh transistor having a gate configured to be electrically connected to the third node, a first electrode configured to be electrically connected to the first voltage terminal to receive a first voltage, and a second electrode configured to be electrically connected to the first node;
an eighth transistor having a gate configured to be electrically connected to the third node, a first electrode configured to be electrically connected to the first node, and a second electrode configured to be electrically connected to the second voltage terminal to receive a second voltage; and
a second storage capacitor having a first terminal configured to be electrically connected to the first node and a second terminal configured to be electrically connected to the second voltage terminal to receive the second voltage,
wherein the seventh transistor is a P-type transistor and the eighth transistor is an N-type transistor.

9. The shift register unit according to claim 4, wherein the logic NAND circuit comprises:
a ninth transistor having a gate configured to be electrically connected to the first node, a first electrode configured to be electrically connected to the first voltage terminal to receive a first voltage, and a second electrode configured to be electrically connected to the fourth node;
a tenth transistor having a gate configured to be electrically connected to the first clock signal terminal to receive the first clock signal, a first electrode configured to be electrically connected to the first voltage terminal to receive the first voltage, and a second electrode configured to be electrically connected to the fourth node;
an eleventh transistor having a gate configured to be electrically connected to the first node and a first electrode configured to be electrically connected to the fourth node; and
a twelfth transistor having a gate configured to be electrically connected to the first clock signal terminal to receive the first clock signal, a first electrode configured to be electrically connected to a second electrode of the eleventh transistor, and a second electrode configured to be electrically connected to the second voltage terminal to receive a second voltage,
wherein the ninth transistor and the tenth transistor are P-type transistors, and the eleventh transistor and the twelfth transistor are N-type transistors.

10. The shift register unit according to claim 4, wherein the first inverter circuit comprises:
a thirteenth transistor having a gate configured to be electrically connected to the fourth node, a first electrode configured to be electrically connected to the first voltage terminal to receive a first voltage, and a second electrode configured to be electrically connected to the output terminal; and
a fourteenth transistor having a gate configured to be electrically connected to the fourth node, a first electrode configured to be electrically connected to the output terminal, and a second electrode configured to be electrically connected to the second voltage terminal to receive a second voltage,
wherein the thirteenth transistor is a P-type transistor, and the fourteenth transistor is an N-type transistor.

11. The shift register unit according to claim 2, further comprising a buffer de-noising circuit, wherein:
the buffer de-noising circuit is electrically connected to the first voltage terminal, the second voltage terminal, the output terminal, and the data output circuit, and is configured to buffer, de-noise and output the signal output by the data output circuit to the output terminal.

12. The shift register unit according to claim 11, wherein the buffer de-noising circuit comprises a second inverter circuit and a third inverter circuit, wherein:
the second inverter circuit is electrically connected to the first voltage terminal, the second voltage terminal, and the data output circuit, and is configured to invert and output the signal output by the data output circuit to the third inverter circuit; and
the third inverter circuit is electrically connected to the first voltage terminal, the second voltage terminal, and the output terminal, and is configured to invert and output the signal output by the second inverter circuit to the output terminal.

13. The shift register unit according to claim 12, wherein:
the second inverter circuit comprises:
a fifteenth transistor having a gate configured to be electrically connected to the data output circuit, a first electrode configured to be electrically connected to the first voltage terminal to receive a first voltage, and a second electrode configured to be electrically connected to the third inverter circuit; and
a sixteenth transistor having a gate configured to be electrically connected to the gate of the fifteenth transistor, a first electrode configured to be electrically connected to the second electrode of the fifteenth transistor, and a second electrode configured to be electrically connected to the second voltage terminal to receive a second voltage; and
the third inverter circuit comprises:
a seventeenth transistor having a gate configured to be electrically connected to the second inverter circuit, a first electrode configured to be electrically connected to the first voltage terminal to receive the first voltage, and a second electrode configured to be electrically connected to the output terminal; and
an eighteenth transistor having a gate configured to be electrically connected to the gate of the seventeenth transistor, a first electrode configured to be electrically connected to the second electrode of the seventeenth transistor, and a second electrode configured to be electrically connected to the second voltage terminal to receive the second voltage, and
wherein the fifteenth transistor and the seventeenth transistor are P-type transistors, and the sixteenth transistor and the eighteenth transistor are N-type transistors.

14. A gate driving circuit, comprising a plurality of cascaded shift register units according to claim 1.

15. A display apparatus, comprising the driving apparatus according to claim 14.

16. A driving method of the shift register unit according to claim 1, comprising:
in a first phase, providing the first clock signal at a low level and the second clock signal at a high level, and registering, by the data register circuit, the input signal at the first node;
in a second phase, providing the first clock signal at a high level and the second clock signal at a low level, and outputting, by the data output circuit, the input signal registered at the first node to the output terminal; and
in a third phase, providing the first clock signal at a low level and the second clock signal at a high level, resetting, by the data register circuit, the first node and resetting, by the data output circuit, the output terminal.

17. A gate driving circuit, comprising a plurality of cascaded shift register units according to claim 2.

18. A gate driving circuit, comprising a plurality of cascaded shift register units according to claim 3.

19. A display apparatus, comprising the driving apparatus according to claim 17.

20. A display apparatus, comprising the driving apparatus according to claim 18.
